(19) United States
(12) Patent Application Publication
(10) Pub. No.: US 2016/0007486 A1
(43) Pub. Date: Jan. 7, 2016

(54) PACKAGE SUBSTRATE

(71) Applicant: SAMSUNG ELECTRO-MECHANICS CO., LTD., Suwon-Si (KR)

(72) Inventors: Yong Suk KIM, Yongin-si (KR); Taek Jung LEE, Hwaseong-si (KR); Byeung Gyu CHANG, Suwon-Si (KR); Doo Young KIM, Yongin-si (KR); Byoung Hwa LEE, Seongnam-si (KR)

(21) Appl. No.: 14/754,261

(22) Filed: Jun. 29, 2015

(30) Foreign Application Priority Data
Jul. 2, 2014 (KR) 10-2014-0082701

(51) Int. Cl. H05K 5/00; H05K 3/00; H05K 3/30; H05K 5/04

(52) U.S. Cl. CPC H05K 5/0052; H05K 5/04; H05K 5/0034; H05K 3/0058; H05K 3/30

(57) ABSTRACT

There is provided a package substrate including: a substrate on which a circuit layer and an insulating layer are stacked; a metal post provided in an outside region of at least any one of an upper surface and a lower surface of the substrate; an electronic component mounted in a cavity formed by the metal post; and a metal lid bonded to an upper portion of the metal post.

This application claims the benefit under 35 U.S.C. Section [120, 119, 119(e)] of Korean Patent Application Serial No. 10-2014-0082701, entitled “Package Substrate” filed on Jul. 2, 2014, which is hereby incorporated by reference in its entirety into this application.

### BACKGROUND OF THE INVENTION

1. Technical Field

The present disclosure relates to a substrate, and more particularly, to a package substrate on which electronic components are mounted.

2. Description of the Related Art

Recently, as a demand for small, multi-functional electronic devices such as a tablet PC and a smart phone is increasingly accelerated, the number of electronic components used in the electronic devices is inclined to be increased accordingly. As a result, a technology of mounting a large number of electronic components on a substrate at high density has been demanded.

To keep pace with a demand for a system integration technology, a package substrate for implementing high performance while occupying a small space has been widely used.

The package substrate is completed by mounting the electronic components on the substrate and sealing the electronic components using materials such as resin. Herein, to secure the space in which the electronic components are mounted, a cavity having an empty space is formed on the substrate toward a direction in which the electronic components are mounted.

However, the method has a problem in that it is difficult to accurately process a cavity region and internal circuits of the substrate may be damaged during a plating process, an etching process, or the like.

In particular, a method for optionally processing a position of a cavity in a finished stacked printed circuit board by a laser drill is hard to control a depth and thus often damages the substrate.

Further, a method for processing cavities using router, punching, or the like has a very large difference in processing precision and needs to individually form the cavities. As a result, the method has a problem in that process efficiency may be remarkably reduced and manufacturing costs may be increased due to the low productivity.

### SUMMARY OF THE INVENTION

An object of the present disclosure is to provide a package substrate in which a cavity is formed by a photolithography process, not by a router process or a punching process and a method for manufacturing the same capable of solving problems such as product deformation and reduction in dimension precision which may occur at the time of processing the cavity.

According to an exemplary embodiment of the present disclosure, there is provided a package substrate in which a post for forming a cavity in which an electronic component will be mounted is made of a metal material to improve an adhesion with a metal lid bonded thereon.

Further, according to an exemplary embodiment of the present disclosure, there is provided a package substrate in which a metal post is configured of a vertical part having a predetermined height and a horizontal part which is bonded to an upper portion of the vertical part and is formed to have a larger width than the vertical part.

To manufacture the package substrate as described above, the present disclosure provides a method for manufacturing a package substrate for forming the metal post by a plating process. In detail, the present disclosure provides a method for manufacturing a package substrate capable of easily controlling a height and a width of the metal post by attaching a resist to a substrate, removing a region in which the metal post in the resist is formed, that is, an outside portion of the resist, and then forming the metal post using a plating process by an electroplating method, and the like.

### BRIEF DESCRIPTION OF THE DRAWINGS

FIG. 1 is a cross-sectional view of a package substrate according to an exemplary embodiment of the present disclosure.

FIG. 2 is a plan view of the package substrate according to the exemplary embodiment of the present disclosure.

FIG. 3 is a cross-sectional view of the package substrate according to another exemplary embodiment of the present disclosure.

FIG. 4 is a flow chart sequentially illustrating a method for manufacturing a package substrate according to the exemplary embodiment of the present disclosure.

FIGS. 5 to 11 are process diagrams illustrating each step of FIG. 4.

FIGS. 12 to 17 are process diagrams of a method for manufacturing a package substrate according to another exemplary embodiment of the present disclosure.

### DESCRIPTION OF THE PREFERRED EMBODIMENTS

Various advantages and features of the present disclosure and methods accomplishing them will become apparent from the following description of exemplary embodiments with reference to the accompanying drawings. However, the present disclosure is not limited to exemplary embodiments set forth herein, but may be modified in many different forms. These exemplary embodiments may be provided so that the scope of the present disclosure will be thorough and complete, and will fully convey the scope of the present disclosure to those skilled in the art. Like reference numerals throughout the specification denote like elements.

Terms used in the present specification are for explaining exemplary embodiments rather than limiting the present disclosure. Unless explicitly described to the contrary, a singular form includes a plural form in the present specification. The word used in the specification “comprise” and variations such as “comprises” or “comprising,” will be understood to imply the inclusion of stated constituents, steps, operations and/or elements but not the exclusion of any other constituents, steps, operations and/or elements.

Hereinafter, a configuration and an acting effect of exemplary embodiments of the present disclosure will be described in more detail with reference to the accompanying drawings.

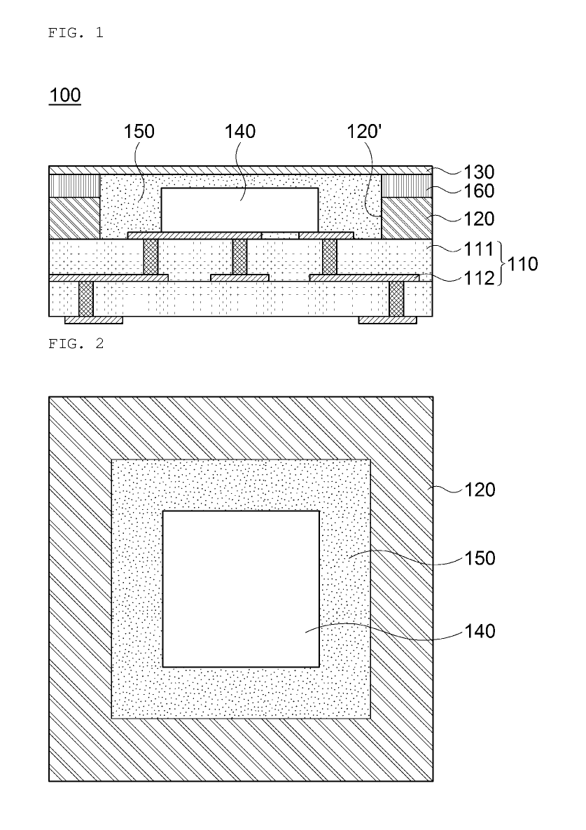

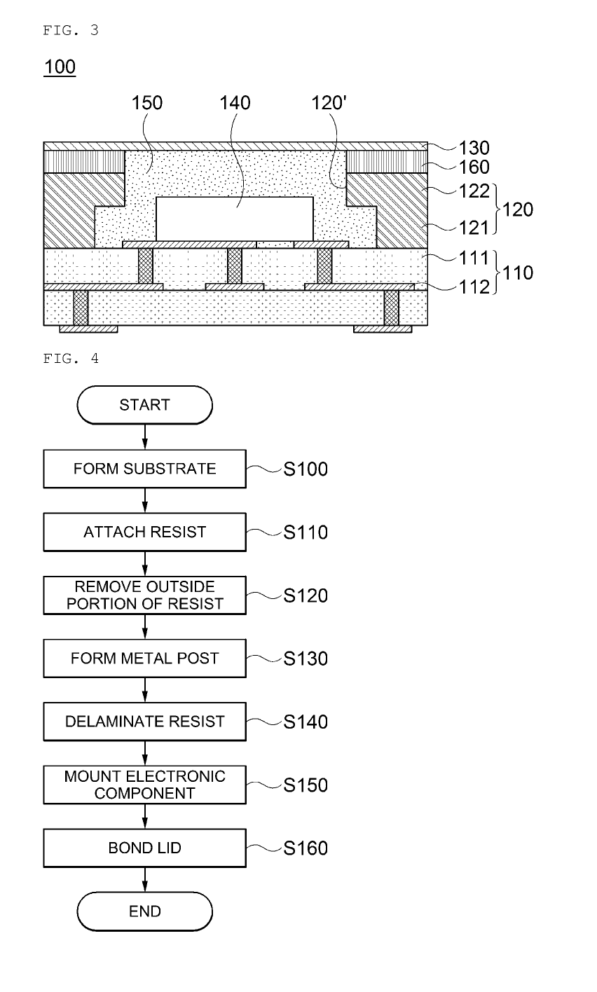

FIG. 1 is a cross-sectional view of a package substrate according to an exemplary embodiment of the present disclosure and FIG. 2 is a plan view of the package substrate according to the exemplary embodiment of the present disclosure. For reference, FIG. 2 illustrates the package substrate except for a metal lid and a metal layer for clearly describing features of the present disclosure. Additionally, components shown in the accompanying drawings are not necessarily shown to scale. For example, sizes of some components shown in the accompanying drawings may be exaggerated as compared with other components in order to assist in the understanding of the exemplary embodiments of the present disclosure.

Referring to FIGS. 1 and 2, a package substrate 100 according to an exemplary embodiment of the present disclosure includes a substrate 110 which is a base and an electronic component 140 which is mounted on the substrate 110. In this configuration, the electronic component 140 is mounted in a cavity 120′ which is formed by a metal post 120.

The substrate 110 is a wiring board which is formed to have a package size which is equal to or less than, for example, 1612 and is configured by stacking a circuit layer 111 and an insulating layer 112. The exemplary embodiment of the present disclosure describes, for example, a multilayer substrate in which the circuit layer 111 is configured in three layers but is not necessarily limited thereto. For example, the substrate 110 may also be a single-sided substrate or a double-sided substrate.

The circuit layer 111 is divided into a ground wiring forming a ground region, a power supply wiring which is a power supply means, a signal wiring performing a signal transfer function, and the like according to use, in which the circuit layer 111 which is an outermost layer may include a pad which is directly connected to the electronic component 140 through a solder ball (not illustrated). Further, each layer is electrically connected to each other through a via.

The insulating layer 112 serves to perform interlayer insulation and protect the circuit layer 111 and as a material of the insulating layer 112, thermosetting resin such as epoxy, thermoplastic resin such as polyimide, photo-curable resin, and the like may be used. Further, to impart stiffness, prepreg in which a stiffener such as glass fiber or inorganic filler is impregnated in these resins may also be used.

The metal post 120 is provided in an outside region of at least any of an upper surface and a lower surface of the substrate 110. As such, as the metal post 120 is provided at an edge of the substrate 110, the cavity 120′ having an empty space is formed inside the metal post 120 and the electronic component 140 is mounted therein by a wire bonding method, a bump bonding method, or the like.

The electronic component 140 may be appropriately selected from active devices such as an RF chip and an IC chip or passive devices such as a resistor, a capacitor, and an inductor. Further, the exemplary embodiment of the present disclosure illustrates that one electronic component 140 is embedded in the cavity, which is only one example and therefore the number of electronic components 140 is not limited.

A height of the metal post 120 is determined depending on a thickness of the mounted electronic component 140 and the metal post 120 is formed to have a larger height than the thickness of the electronic component 140 so that the electronic component 140 is completely mounted in the cavity 120′.

Further, a width of the metal post 120 is determined depending on a size of the electronic component 140. For example, when the electronic component 140 having a relatively small size such as an inductor element or a capacitor element is mounted, the metal post 120 is formed to have a larger width and to the contrary, when the electronic component 140 having a large size such as the RF chip or the IC chip is mounted, the metal post 120 is formed to have a smaller width.

A metal lid 130 for covering the cavity 120′ is bonded to the upper portion of the metal post 120. The metal lid 130 is formed to have the same size as the substrate 110 and thus the metal post 120 is bonded to an edge of the metal lid 130. According to the above structure, the cavity 120′ is a sealed space and the electronic component 140 is blocked from the outside.

The metal post 120 and the metal lid 130 are made of the same metal material to increase interfacial adhesion. For example, the metal post 120 and the metal lid 130 may be made of at least one metal material selected from a group consisting of alloy, Kovar, nickel (Ni), cobalt (Co), and chromium (Cr) which have a low coefficient of thermal expansion. In this case, bonding methods, such as seam welding, laser welding, and brazing welding, may be used and thus the adhesion between the metal post 120 and the metal lid 130 is more strengthened.

A metal layer 160 may be further provided between the metal post 120 and the metal lid 130. The metal layer 160 is a surface treatment layer which is formed by performing a chemical vapor deposition method (CVD), a physical vapor deposition method (PVD), an electroless plating method, and the like on an upper surface of the metal post 120 and may be made of any one or at least two alloys of metals having a low thermal diffusion coefficient, for example, Cu, Ni, Pd, Au, Sn, Ag, and Co or. Further, the exemplary embodiment of the present disclosure describes, for example, the metal layer 160 having a single layer structure but is not limited thereto and therefore the metal layer 160 may be formed in a multilayer structure in which an Au/Sn alloy layer and an Ag/Sn alloy layer are stacked, for example.

As such, when the metal layer 160 is provided between the metal post 120 and the metal lid 130, even though the metal post 120 and the metal lid 130 are made of different metal materials, cracks, warpage, and the like due to a difference in coefficients of thermal expansion may be prevented and thus the adhesion between the metal post 120 and the metal lid 130 may be strengthened.

According to another exemplary embodiment of the present disclosure, the package substrate 100 may include the metal post 120 which is configured of a vertical part and a horizontal part.

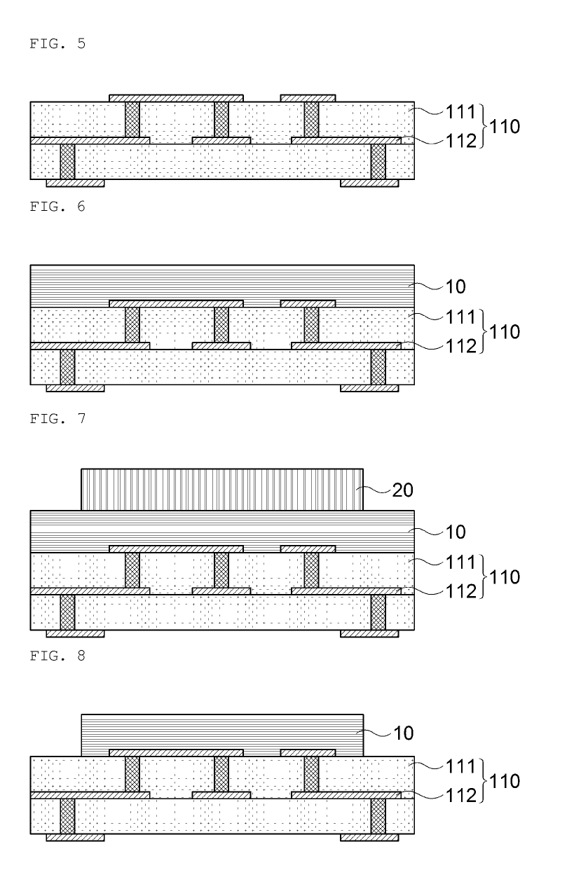

FIG. 3 is a cross-sectional view of the package substrate according to another exemplary embodiment of the present disclosure. Referring to FIG. 3, the metal post 120 is configured of a vertical part 121 and a horizontal part 122 which is bonded to an upper portion of the vertical part 121 and is formed to have a larger width than the vertical part 121. One end of the horizontal part 122 protrudes toward a cavity 120′ and thus the metal post 120 has a structure in a ‘┌’ or ‘┐’-letter form.

In this structure, the metal lid 130 is bonded to the upper surface of the horizontal part 122 (or bonded to the upper surface of the horizontal part 122, having the metal layer 160 disposed therebetween), and as a result, the adhesion between the metal post 120 and the metal lid 130 is more strengthened due to the increase in the bonded area.

Describing the package substrate 100 according to the exemplary embodiment of the present disclosure with reference to back to FIG. 1, a sealing material 150 formed to seal the electronic component 140 may be provided in the cavity 120′ As the sealing material 150, an epoxy mold compound (EMC) may be used and thus the sealing material 150 absorbs outside impact to prevent the electronic component 140 from being damaged.

Hereinafter, a method of manufacturing a package substrate according to an exemplary embodiment of the present disclosure will be described.

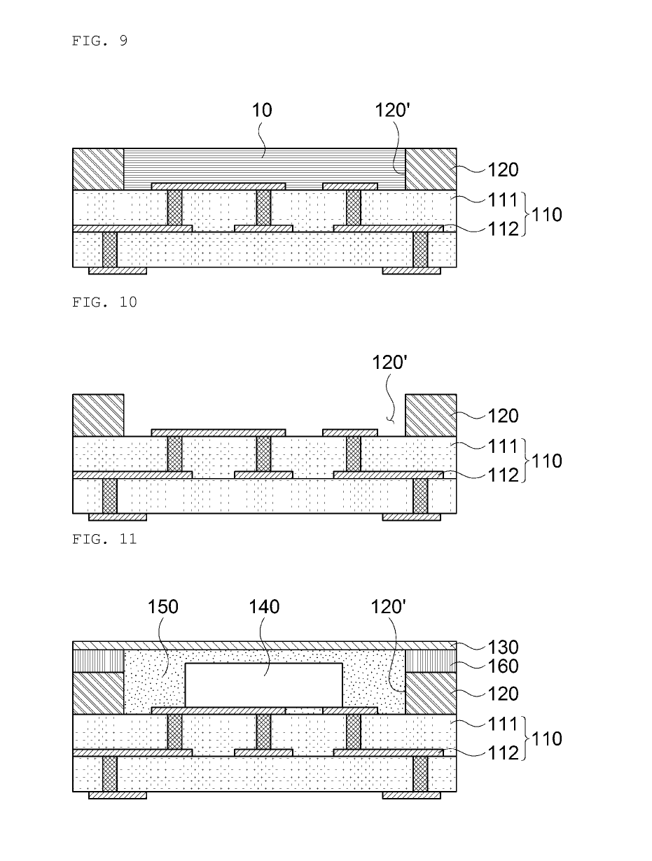

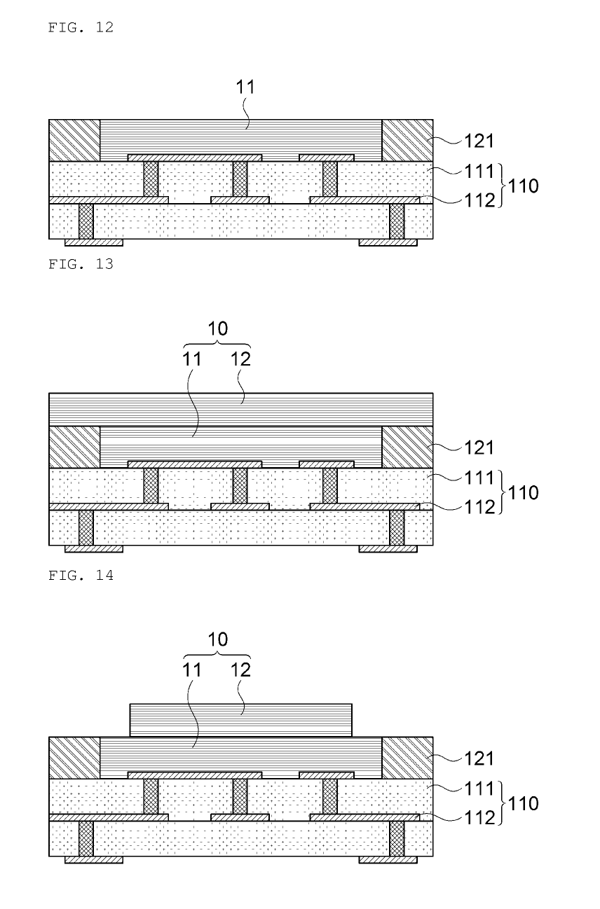

FIG. 4 is a flow chart sequentially illustrating a method for manufacturing a package substrate according to the exemplary embodiment of the present disclosure and FIGS. 5 to 11 are process diagrams illustrating each step of FIG. 4.

Referring to FIGS. 5 to 11, the method for manufacturing a package substrate according to the exemplary embodiment of the present disclosure first forms the substrate 110 configured by stacking the circuit layer 111 and the insulating layer 112 (S100, FIG. 5).

The circuit layer 111 may be formed by a general circuit forming process known to those skilled in the art, for example, a semi-additive process, a modified semi-additive process (MSAP), or a subtractive process, and the like. The exemplary embodiment of the present disclosure illustrates, for example, the multilayer substrate having a 3 layer structure, but unlike this, the substrate 110 may be formed as a single-sided substrate or a double-sided substrate.

Next, a resist 10 made of photosensitive resin is attached to at least any one of the upper surface and the lower surface of the substrate 110 (S110, FIG. 6).

The resist 10 may be formed by being coated in a liquid-state form or laminating a dry-state resin film. Further, as resin forming the resist 10, both of a negative type in which a portion to which light is irradiated is cured and thus is not dissolved by a developer and a positive type in which a portion to which light is irradiated is dissolved by the developer may be used. The exemplary embodiment of the present disclosure describes that the positive type resist 10 is used.

Next, an outside portion of the resist 10 is removed (S120, FIGS. 7 and 8).

In a region in which the resist 10 is removed, the surface of the substrate 110 is exposed to the outside and the metal post 120 is formed therein. Therefore, considering the size of the electronic component 140 which is mounted at the time of removing the resist 10, for example, when the size of the electronic component 140 is large, the removed width is reduced, and to the contrary, when the size of the electronic component 140 is small, the removed width is increased.

The removal of the resist 10 may be progressed by disposing a mask 20 on the remaining portion except for the outside portion of the resist 10 and then performing an exposure and developing process thereon (FIG. 7). After the developing process, in the resist 10, a portion covered with the mask 20 remains as it is and the outside portion to which light is irradiated is removed by a developer (FIG. 8). Therefore, a size of the mask 20 is changed in response to a size of the electronic component 140 and thus a width of the removed region may be easily controlled.

Next, the outside portion of the resist 10 is removed and thus the metal post 120 is formed in the outside region of the substrate 110 exposed to the outside (S130, FIG. 9).

The metal post 120 is formed by plating a metal material. To this end, a seed layer is deposited in the outside region of the substrate 110 and an electroplating process may be performed using the seed layer as a lead-in wire. In this case, a plated amount is controlled depending on the thickness of the electronic component 140. That is, when the mounted electronic component 140 is thick, the plated amount is increased and thus the height of the metal post 120 is increased, and to the contrary, when the mounted electronic component 140 is thin, the plated amount is reduced and thus the height of the metal post 120 may be reduced.

When the metal post 120 is formed, the resist 10 is delaminated (S140, FIG. 10), the electronic component 140 is arranged and mounted in the cavity 120′(S150), and then the metal lid 130 is bonded to the upper portion of the metal post 120, thereby finally completing the package substrate according to the exemplary embodiment of the present disclosure (S160, FIG. 11). In this case, as the bonding of the metal lid 130, the known bonding method such as the seal welding, the laser welding, and the brazing welding may be used.

Meanwhile, to protect the electronic component 140 from outside impact, the sealing material 150 may be filled in the cavity 120′ so that the electronic component 140 is sealed before the metal lid 130 is bonded.

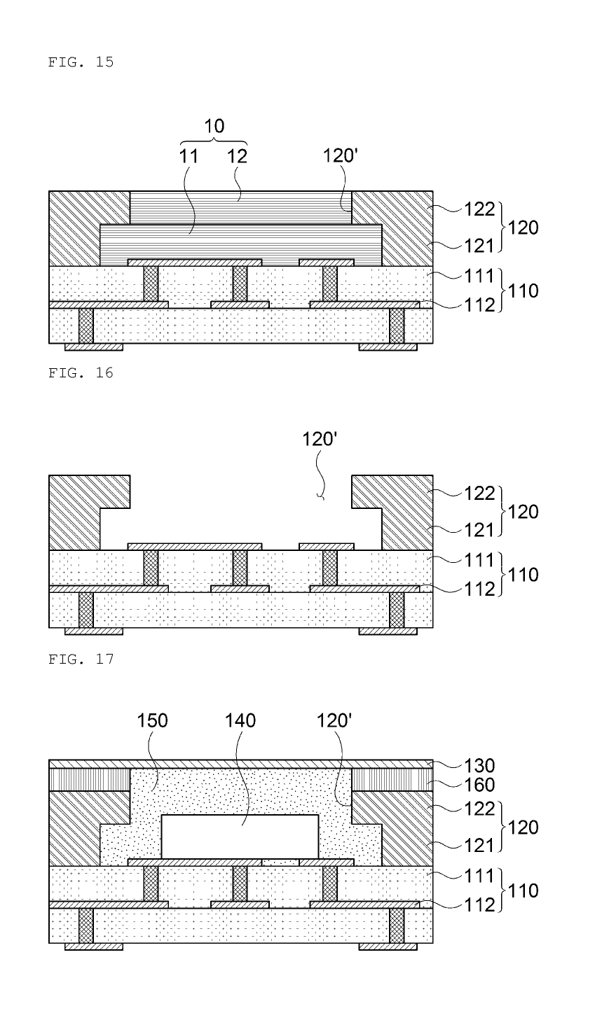

FIGS. 12 to 17 are process diagrams of a method for manufacturing a package substrate according to another exemplary embodiment of the present disclosure. The method for manufacturing a package substrate including the metal post 120 having the structure of FIG. 3 will be described with reference to FIGS. 12 to 17.

FIG. 12 illustrates a process up to the steps in which the vertical part 121 of the metal post 120 is formed on the substrate 110 and the vertical part 121 of the metal post 120 is formed by the same processes as the processes illustrated in FIGS. 5 to 9. Therefore, a detailed description thereof will be omitted. However, according to the exemplary embodiment of the present disclosure, the resist 10 is divided into a first resist 11 for forming the vertical part 121 and a second resist 12 for forming the horizontal part 122 and the resist illustrated in FIG. 12 becomes the first resist 11.

Next, the second resist 12 is stacked on an upper portion of the first resist 11 including the vertical part 121 (FIG. 13).

Next, an outside portion of the second resist 12 is removed. In this case, the outside portion of the second resist 12 is removed larger than the width of the vertical part 121 (FIG. 14). The removal method is the same as the processes of FIGS. 7 and 8 and therefore a detailed description thereof will be omitted.

Next, the outside portion of the second resist 12 is removed and thus the region exposed to the outside is subjected to the electroplating process to form the horizontal part 122 (FIG. 15) and when the first resist 11 and the second resist 12 are delaminated, the metal post 120 having the ‘ [symbol] ’ or ‘ [symbol] ’-letter structure is formed (FIG. 16). Next, the electronic component 140 is mounted in the cavity 120′ and the metal lid 130 is bonded to the upper portion of the horizontal part 122 to finally complete the package substrate having the structure of FIG. 3 (FIG. 17).

According to the exemplary embodiments of the present disclosure, it is possible to manufacture products requiring high reliability against the increase in interfacial adhesion between the metal post and the metal lid.

Further, it is possible to reduce the dimensional deviation of the cavity by not forming the cavity by the router process or the punching process in as the related art and thus prevent the misalign at the time of mounting the electronic components in the cavity.

The present disclosure has been described in connection with what is presently considered to be practical exemplary embodiments. Although the exemplary embodiments of the present disclosure have been described, the present disclosure may be also used in various other combinations, modifications and environments. In other words, the present disclosure may be changed or modified within the range of concept of the disclosure disclosed in the specification, the range equivalent to the disclosure and/or the range of the technology or knowledge in the field to which the present disclosure pertains. The exemplary embodiments described above have been provided to explain the best state in carrying out the present disclosure. Therefore, they may be carried out in other states known to the field to which the present disclosure pertains in using other disclosures such as the present disclosure and also be modified in various forms required in specific application fields and usages of the disclosure. Therefore, it is to be understood that the disclosure is not limited to the disclosed embodiments. It is to be understood that other embodiments are also included within the spirit and scope of the appended claims.

What is claimed is:

1. A package substrate, comprising:
a substrate configured by stacking a circuit layer and an insulating layer;
a metal post provided in an outside region of at least any one of an upper surface and a lower surface of the substrate;
an electronic component mounted in a cavity formed by the metal post; and
a metal lid bonded to an upper portion of the metal post.

2. The package substrate according to claim 1, wherein the metal post and the metal lid are made of the same metal material.

3. The package substrate according to claim 1, wherein the metal post and the metal lid are made of at least one metal material selected from a group consisting of Kovar, alloy, nickel (Ni), cobalt (Co), and chromium (Cr).

4. The package substrate according to claim 1, wherein a height of the metal post is determined depending on a thickness of the electronic component.

5. The package substrate according to claim 1, wherein a width of the metal post is determined depending on a size of the electronic component.

6. The package substrate according to claim 1, wherein the electronic component is at least any one selected from a group consisting of an RF chip, an IC chip, a capacitor, an inductor, and a resistor.

7. The package substrate according to claim 1, further comprising:
a sealing material provided in the cavity to seal the electronic component.

8. The package substrate according to claim 1, wherein the metal post is configured of a vertical part and a horizontal part which is bonded to an upper portion of the vertical part and formed to have a larger width than the vertical part.

9. The package substrate according to claim 1, further comprising:
a metal layer provided between the metal post and the metal lid.

10. A method for manufacturing a package substrate, comprising:
forming a substrate configured by stacking a circuit layer and an insulating layer;
attaching a resist to at least any one of an upper surface and a lower surface of the substrate;
removing an outside portion of the resist;
forming a metal post in an outside region of the substrate which is exposed to the outside by removing the outside portion of the resist;
delaminating the resist; and
mounting an electronic component in a cavity formed by the metal post and bonding a metal lid to an upper portion of the metal post.

11. The method according to claim 10, wherein in the removing of the outside portion of the resist, a mask is disposed in the remaining portion except for the outside portion of the resist and then is subjected to an exposure and developing process.

12. The method according to claim 11, wherein a size of the mask is changed depending on a size of the electronic component.

13. The method according to claim 10, wherein in the forming of the metal post, the outside region of the substrate is plated with a metal material.

14. The method according to claim 13, wherein a plated amount of the metal material is controlled depending on a thickness of the electronic component.

15. The method according to claim 10, wherein the bonding of the metal lid is performed using at least any one of seam welding, laser welding, and brazing welding.

16. The method according to claim 10, wherein prior to the bonding of the metal lid, a sealing material is filled in the cavity to seal the electronic component.

17. A method for manufacturing a package substrate, comprising:
forming a substrate configured by stacking a circuit layer and an insulating layer;
bonding a first resist to at least any one of an upper surface and a lower surface of the substrate;
removing an outside portion of the first resist;
forming a vertical part of a metal post in an outside region of the substrate which is exposed to the outside by removing the outside portion of the first resist;
stacking a second resist on an upper portion of the first resist including the vertical part;
removing an outside portion of the second resist at a larger width than a width of the vertical part;
forming a horizontal part of the metal post in a region which is exposed to the outside by removing the outside portion of the second resist;
delaminating the first and second resists; and
mounting an electronic component in a cavity formed by the vertical part and the horizontal part of the metal post and bonding a metal lid to an upper portion of the horizontal part.
